(19) United States
(12) Patent Application Publication
(10) Pub. No.: US 2026/0150362 A1
(43) Pub. Date: May 28, 2026

(54) MANUFACTURING METHOD OF GATE OXIDE LAYER

(71) Applicant: ProAsia Semiconductor Corporation, Hsinchu City (TW)

(72) Inventor: Wen-Chang Hsu, Hsinchu City (TW)

(21) Appl. No.: 19/193,306

(22) Filed: Apr. 29, 2025

(30) Foreign Application Priority Data
Nov. 25, 2024 (TW) 113145277

(51) Int. Cl. H01L 21/28; C23C 16/40; C23C 16/455; H01L 21/04

(52) U.S. Cl. CPC H10D 64/0134; C23C 16/402; C23C 16/45542; H10D 64/01342; H10D 64/01344; H10D 64/01366

(57) ABSTRACT

A manufacturing method of a gate oxide layer is provided. The manufacturing method comprises the following steps. First, a silicon-containing substrate is provided. Next, a first oxygen plasma deposition is applied to form a first silicon dioxide (SiO₂) layer covering the silicon-containing substrate. Then, a second oxygen plasma deposition is applied to form a second silicon dioxide (SiO₂) layer over the first silicon dioxide layer. Finally, a third oxygen plasma is applied to bombard the second silicon dioxide layer.

### CROSS-REFERENCES TO RELATED APPLICATIONS

This application claims the benefit of priority to Taiwanese Patent Application No. 113145277 filed on Nov. 25, 2024, which is hereby incorporated by reference in its entirety.

### BACKGROUND OF THE INVENTION

### Field of the Invention

This invention relates to a method for manufacturing a gate oxide layer, and in particular to a method for manufacturing a gate oxide layer with reduced interface defect density.

### Descriptions of the Related Art

The gate oxide layer is a critical component in semiconductor devices such as Metal Oxide Semiconductor Field Effect Transistors (MOSFETs) and High Electron Mobility Transistors (HEMTs). A commonly used material for the gate oxide layer is silicon dioxide (SiO₂), which primarily serves to insulate and control the gate voltage to regulate electron flow in the semiconductor channel.

The quality, thickness, and dielectric constant of the gate oxide layer directly impact the electrical performance of semiconductor devices, including threshold voltage, on-state current, and leakage current. As device dimensions continue to shrink, the requirements for the film quality of the gate oxide layer become increasingly stringent. Additionally, the conventional process for preparing gate oxide layers in transistor devices typically involves high-temperature oxidation in a furnace tube. This method not only consumes silicon-containing substrates (e.g., silicon carbide substrates) but also introduces issues such as roughness at the interface between the silicon-containing substrate and silicon dioxide, interface defects (Dit), and carbon residues. These problems increase leakage current and reduce switching speed. Over time, they can degrade the voltage withstand capability of the gate oxide layer, eventually leading to device aging and reduced reliability. Therefore, improving the film quality of the gate oxide layer is an urgent challenge for the industry.

### SUMMARY OF THE INVENTION

The main objective of this invention is to provide a method for manufacturing a high quality gate oxide film. By utilizing a stepwise energy, multi-stage oxygen plasma enhanced atomic layer deposition (PEALD) technique, a multilayer oxide structure is formed on a silicon-containing substrate to reduce surface defects and carbon residues, thereby enhancing the uniformity and electrical performance of the oxide film.

To achieve the above objective, this invention provides a method for manufacturing a gate oxide layer, comprising the following steps. First, provide a silicon-containing substrate. Next, perform a first oxygen plasma deposition to form a first silicon dioxide layer covering the silicon-containing substrate. Then, perform a second oxygen plasma deposition to form a second silicon dioxide layer covering the first silicon dioxide layer. Finally, apply a third oxygen plasma to bombard the second silicon dioxide layer.

In one embodiment of the manufacturing method of this invention, the step of providing a silicon-containing substrate comprises a step of providing either a silicon carbide substrate or a silicon substrate.

In one embodiment of the manufacturing method of this invention, the step of performing a first oxygen plasma deposition is to provide an oxygen plasma enhanced atomic layer deposition (PEALD) at 10 to 20 watts (W) to form a first silicon dioxide layer with a thickness of 10 to 20 angstroms (Å) covering the silicon-containing substrate.

In one embodiment of the manufacturing method of this invention, the step of performing a second oxygen plasma deposition is to provide an oxygen plasma enhanced atomic layer deposition (PEALD) at 100 to 300 watts (W) to form a second silicon dioxide layer with a thickness of 400 to 500 angstroms (Å) covering the first silicon dioxide layer.

In one embodiment of the manufacturing method of this invention, the step of applying a third oxygen plasma is to provide an oxygen plasma at 1500 to 2000 watts (W) to bombard the second silicon dioxide layer, thereby increasing the density of the second silicon dioxide layer.

In one embodiment of the manufacturing method of this invention, the method further includes a step of performing a high-temperature annealing treatment after the step of applying the third oxygen plasma.

In one embodiment of the manufacturing method of this invention, the step of performing a high-temperature annealing treatment is to provide a high-temperature annealing treatment using nitric oxide (NO) or nitrous oxide (N₂O).

To achieve the above objective, this invention provides another method for manufacturing a gate oxide layer, comprising the following steps. First, provide a silicon carbide substrate. Next, perform multi-stage oxygen plasma enhanced atomic layer deposition (PEALD) to sequentially form a first silicon dioxide layer covering the silicon carbide substrate and then a second silicon dioxide layer covering the first silicon dioxide layer. Finally, apply an oxygen plasma to bombard the second silicon dioxide layer.

In another embodiment of the manufacturing method of this invention, the step of performing multi-stage oxygen plasma enhanced atomic layer deposition comprises providing an oxygen plasma enhanced atomic layer deposition (PEALD) with a power of 10 to 20 watts (W) to form a first silicon dioxide layer with a thickness of 10 to 20 angstroms (Å) covering the silicon carbide substrate, followed by providing an oxygen plasma enhanced atomic layer deposition (PEALD) with a power of 100 to 300 watts (W) to form a second silicon dioxide layer with a thickness of 400 to 500 angstroms (Å) covering the first silicon dioxide layer.

In another embodiment of the manufacturing method of this invention, the step of applying an oxygen plasma to bombard the second silicon dioxide layer is to provide an oxygen plasma with a power of 1500 to 2000 watts (W) to bombard the second silicon dioxide layer, thereby increasing the density of the second silicon dioxide layer.

In another embodiment of the manufacturing method of this invention, the method further includes a step of performing a high-temperature annealing treatment using nitric oxide (NO) or nitrous oxide (N₂O) after the step of applying the oxygen plasma to bombard the second silicon dioxide layer.

After referring to the drawings and the embodiments described subsequently, those skilled in the art will understand the other objectives of the present invention, as well as the technical means and embodiments of the present invention.

### BRIEF DESCRIPTION OF THE DRAWINGS

FIG. 1 is a schematic diagram illustrating the manufacturing of a gate oxide layer in one embodiment of this invention.

FIG. 2 is a schematic diagram of the process steps for manufacturing the gate oxide layer of this invention.

### DETAILED DESCRIPTION OF THE PREFERRED EMBODIMENT

In the following description, the present invention will be explained with reference to various embodiments thereof. These embodiments of the present invention are not intended to limit the present invention to any specific environment, application or particular method for implementations described in these embodiments. Therefore, the description of these embodiments is for illustrative purposes only and is not intended to limit the present invention. It shall be appreciated that, in the following embodiments and the attached drawings, a part of elements not directly related to the present invention may be omitted from the illustration, and dimensional proportions among individual elements and the numbers of each element in the accompanying drawings are provided only for ease of understanding but not to limit the present invention.

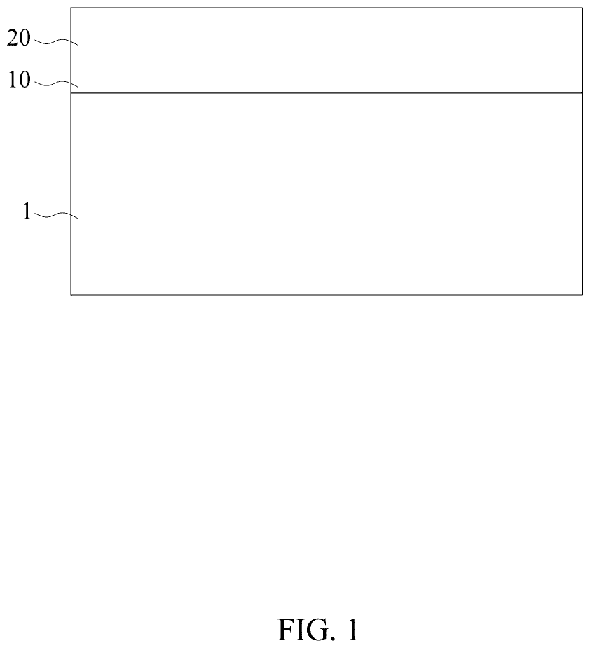

Referring to FIG. 1, it illustrates a schematic diagram of a method for manufacturing a gate oxide layer in one embodiment of this invention, particularly for manufacturing a gate oxide layer in a transistor device. It should be noted that components not directly related to the invention are omitted from the following embodiments and drawings for clarity. Specifically, as shown in FIG. 1, a silicon-containing substrate is first provided. This silicon-containing substrate may include, but not limited to, a silicon substrate or a silicon carbide substrate. The following description will use a silicon carbide substrate 1 as an example to illustrate the invention.

Unlike traditional methods using high-temperature thermal oxidation to form gate oxide layers, this invention employs a deposition method to grow the oxide film. Specifically, the invention utilizes oxygen plasma enhanced atomic layer deposition (PEALD) technology with stepwise energy and multi-stage processes to form a gate oxide film on the silicon carbide substrate 1. As shown in FIG. 1, in the first stage, a low-power oxygen plasma deposition is performed, for example, using a PEALD process with a power of 10 to 20 watts (W) to precisely control and form a nanoscale thin film. For instance, a first silicon dioxide layer 10 with a thickness of 10 to 20 angstroms (Å) is formed to cover the silicon carbide substrate 1.

Compared to traditional high-temperature thermal oxidation film growth, the PEALD process in the first stage operates at a lower power and temperature for oxide deposition. This approach leverages the high reactivity of plasma-generated ions and radicals to provide additional energy for the deposition reaction for promoting chemical reactions and reducing the need to heat the substrate as required in traditional processes. Moreover, since the temperature in the first-stage PEALD process is lower than that of conventional thermal oxidation, it helps minimize physical damage to the surface of the silicon carbide substrate during deposition, thereby reducing the defect density at the interface between the silicon carbide substrate and the gate oxide layer.

Continuing with FIG. 1, the second stage of the oxide layer deposition process is performed by using oxygen plasma deposition to form an oxide layer. Unlike the first stage, this stage employs high-power plasma deposition, for example, using a PEALD process with a power of 100 to 300 watts (W) to form a second silicon dioxide layer 20 with a thickness of 400 to 500 angstroms (Å) covering the first silicon dioxide layer 10. The use of higher power in the second stage is feasible because the silicon carbide substrate 1 is already fully covered by a thin first silicon dioxide layer 10. With the protection of the first silicon dioxide layer 10, there is no longer a risk of defect formation or carbon residue on the silicon carbide substrate 1. Thus, the plasma energy can be increased to enhance reactivity and accelerate the deposition rate of the oxide layer until the second silicon dioxide layer 20 reaches the predetermined thickness.

Next, an oxygen plasma is applied to bombard the second silicon dioxide layer 20, thereby increasing its density. Specifically, an oxygen plasma with a power of 1500 to 2000 watts (W), or even up to 3000 to 4000 watts, is used to bombard the second silicon dioxide layer 20. The oxygen molecules and radicals containing in high-energy plasma provided react with the second silicon dioxide layer 20 for further oxidizing the surface material and repairing interface defects and thus increasing the density of the second silicon dioxide layer 20. This step is crucial for improving the quality of the gate oxide layer for enhancing the electrical performance and reliability of the semiconductor device, such as reducing leakage current.

In a preferred embodiment, a high-temperature annealing treatment is performed after the oxygen plasma bombardment step. For example, nitric oxide (NO) or nitrous oxide (N₂O) is used for high-temperature annealing within a temperature range of 900° C. to 1100° C. The decomposition of N₂O at high temperatures generates active nitrogen oxides (e.g., NO, N₂O), which effectively passivate the interface between silicon and silicon dioxide for repairing defects at the interface and improving interface quality. Additionally, during the high-temperature annealing process, N₂O is decomposed to produce nitrogen atoms that can be incorporated into the gate oxide layer for forming a nitrogen-containing oxide layer (SiON). This nitrogen-doped layer enhances the resistance of the oxide layer to electric field breakdown, reduces leakage current, and improves thermal stability.

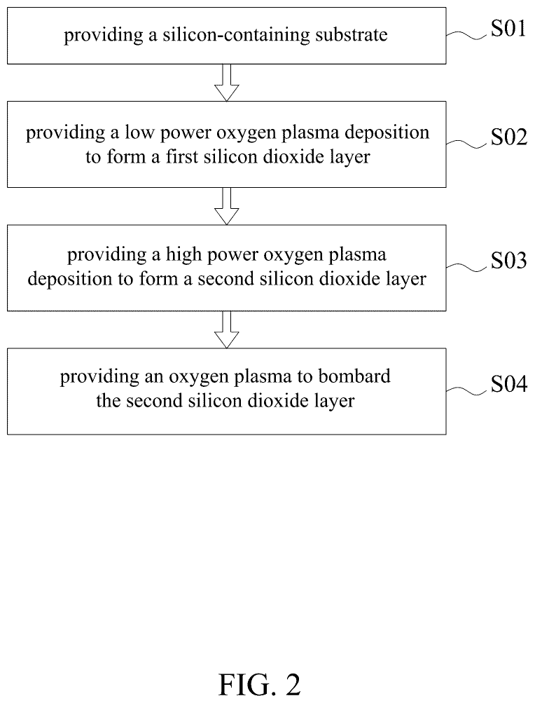

Referring to FIG. 2, it illustrates a schematic diagram of the process steps for manufacturing the gate oxide layer of this invention. First, in step S01, a silicon-containing substrate is provided. Next, in step S02, a low power oxygen plasma deposition is performed to form a first silicon dioxide layer covering the silicon-containing substrate. In step S03, a high power oxygen plasma deposition is performed to form a second silicon dioxide layer covering the first silicon dioxide layer. Finally, in step S04, a third oxygen plasma is applied to bombard the second silicon dioxide layer, thereby increasing its density. Detailed descriptions of the process parameters for each step can be found in the preceding sections and are not repeated here.

The above embodiments are used only to illustrate the implementations of the present invention and to explain the technical features of the present invention, and are not used to limit the scope of the present invention. Any modifications or equivalent arrangements that can be easily accomplished by people skilled in the art are considered to fall within the scope of the present invention, and the scope of the present invention should be limited by the claims of the patent application.

What is claimed is:

1. A manufacturing method of a gate oxide layer, comprising:
providing a silicon-containing substrate;
providing a first oxygen plasma deposition to form a first silicon dioxide layer covering the silicon-containing substrate;
providing a second oxygen plasma deposition to form a second silicon dioxide layer over the first silicon dioxide layer; and
providing a third oxygen plasma to bombard the second silicon dioxide layer.

2. The manufacturing method of a gate oxide layer of claim 1, wherein the step of providing a silicon-containing substrate is to provide one of a silicon carbide substrate and a silicon substrate.

3. The manufacturing method of a gate oxide layer of claim 1, wherein the step of providing a first oxygen plasma deposition is to provide an oxygen plasma enhanced atomic layer deposition (PEALD) at 10 to 20 watts (W) to form the first silicon dioxide layer with a thickness of 10 to 20 angstroms (Å) to cover the silicon-containing substrate.

4. The manufacturing method of a gate oxide layer of claim 1, wherein the step of providing a second oxygen plasma deposition is to provide an oxygen plasma enhanced atomic layer deposition at 100 to 300 watts (W) to form the second silicon dioxide layer with a thickness of 400 to 500 angstroms (Å) to cover the first silicon dioxide layer.

5. The manufacturing method of a gate oxide layer of claim 1, wherein the step of providing a third oxygen plasma is to provide an oxygen plasma at 1500 to 2000 watts (W) to bombard the second silicon dioxide layer for increasing the density of the second silicon dioxide layer.

6. The manufacturing method of a gate oxide layer of claim 1, wherein after the step of providing a third oxygen plasma further comprises a step of providing a high temperature annealing treatment.

7. The manufacturing method of a gate oxide layer of claim 6, wherein the step of providing a high temperature annealing treatment is to provide a high temperature annealing treatment with nitrogen oxide or nitrous oxide (N₂O).

8. A manufacturing method of a gate oxide layer, comprising:
providing a silicon carbide substrate;
providing a multi-stage plasma enhanced atomic layer deposition (PEALD) to form a first silicon dioxide layer covering the silicon carbide substrate and sequentially to form a second silicon dioxide layer covering the first silicon dioxide layer; and
providing an oxygen plasma to bombard the second silicon dioxide layer.

9. The manufacturing method of a gate oxide layer of claim 8, wherein the step of providing the multi-stage plasma enhanced atomic layer deposition is to provide the oxygen plasma enhanced atomic layer deposition at 10 to 20 watts (W) to form the first silicon dioxide layer with a thickness of 10 to 20 angstroms (Å) to cover the silicon carbide substrate and sequentially to provide the oxide plasma enhanced atomic layer deposition at 100 to 300 watts (W) to form the second silicon dioxide layer with a thickness of 400 to 500 angstroms (Å) to cover the first silicon dioxide substrate.

10. The manufacturing method of a gate oxide layer of claim 1, wherein the step of providing a third oxygen plasma is to provide an oxygen plasma at 1500 to 2000 watts (W) to bombard the second silicon dioxide layer for increasing the density of the second silicon dioxide layer.

11. The manufacturing method of a gate oxide layer of claim 8, wherein the step of providing a high temperature annealing treatment is to provide a high temperature annealing treatment with nitrogen oxide or nitrous oxide (N₂O).
